(19) United States
(12) Patent Application Publication
(10) Pub. No.: US 2007/0278661 A1
(43) Pub. Date: Dec. 6, 2007

(54) CIRCUIT BOARD AND MANUFACTURING METHOD THEREOF

(75) Inventor: Chi-Hsing Hsu, Taipei Hsien (TW)

Correspondence Address: J C PATENTS, INC., 4 VENTURE, SUITE 250, IRVINE, CA, 92618, US

(73) Assignee: VIA TECHNOLOGIES, INC., Taipei Hsien (TW)

(21) Appl. No.: 11/464,666

(22) Filed: Aug. 15, 2006

(30) Foreign Application Priority Data
Jun. 6, 2006 (TW) 95119980

(51) Int. Cl. H01L 23/12

(52) U.S. Cl. 257/700

(57) ABSTRACT

A circuit board and a manufacturing method thereof are provided. First, the circuit board has a coaxial signal trace that comprises a conductive line and conductive wall. The conductive wall surrounds part or all of the conductive line. Additionally, the circuit board has a plurality of circuit layers where the coaxial signal trace is located. Secondly, the method for manufacturing the circuit board has several steps including using a module to form a pattern that is made for the circuit layers where part of the conductive wall is encompassed. In the end, through the present invention, the problems from the high frequency signal transmission in electronic apparatus can be solved or reduced.

### CROSS-REFERENCE TO RELATED APPLICATION

This application claims the priority benefit of Taiwan application serial no. 95119980, filed on Jun. 6, 2006. All disclosure of the Taiwan application is incorporated herein by reference.

### BACKGROUND OF THE INVENTION

1. Field of Invention

The present invention is related to a circuit board and its manufacturing method and is particularly related to a circuit board having a coaxial signal trace and its manufacturing method.

2. Description of Related Arts

Since the wireless communication has become the major driving force for the growth of the semiconductor industry, it is important for every semiconductor company to solve the problems during the development of the high-frequency electronic devices.

During the signal transmission of a high-frequency electronic device, there exist some problems, such as impedance, electromagnetic coupling, cross talk, propagation delay, attenuation, skew, rise time degradation, and so on. Thus, it is necessary to develop technologies to overcome these problems. For example, U.S. Pat. No. 7,030,490 presented a wire-bonding structure of an electronic device package structure to improve the signal transmission of high-frequency electronic devices; U.S. Pat. No. 7,002,432 provided a signal trace structure of a circuit board to improve the problems of impedance; and U.S. Pat. No. 6,951,773 showed a package structure to control the problems of impedance. Besides the above patents, there are many patents intending to solve the problems of the high-frequency transmission.

In the present invention, a circuit board and its manufacturing method would be provided to improve the problems triggered by the high-frequency signal transmission, for example, impedance, electromagnetic coupling, cross talk, propagation delay, attenuation, skew, rise time degradation, and so on, a circuit board and its manufacturing method are presented.

### SUMMARY OF THE INVENTION

The present invention provides a circuit board. The circuit board comprises a three-circuit-layer-stacked structure, where a signal trace is enclosed in the structure and a conductive wall encompasses the signal trace.

The present invention provides a substrate manufacturing method. First, a basic substrate having a conductive line is provided. Then, a first dielectric layer is formed on the basic substrate. Later, the first dielectric layer is patterned by a mold to form a first circuit layer. After that, a second circuit layer is formed in the first dielectric layer. Then, a second dielectric layer is formed on the first dielectric layer. Sequentially, the second dielectric layer is patterned by the same or another mold to form a third circuit layer. Additionally, if more layers are required, then keep forming a fourth circuit layer on the second dielectric layer.

The present invention provides a circuit board. The circuit board at least comprises a plurality of circuit layers; a signal trace disposed in one of the circuit layers; and a first conductive wall encompassing the trace signal and disposed in the circuit layers.

In order to the make aforementioned and other features and advantages of the present invention more comprehensible, a plurality of embodiments accompanied with figures is described in details below.

### BRIEF DESCRIPTION OF THE DRAWINGS

FIG. 1 shows a coaxial signal trace structure of one embodiment of the present invention.

FIG. 2 shows the top views of the cross sections of the coaxial signal trace of FIG. 1.

FIG. 3 shows the side views of the cross sections of the coaxial signal trace of FIG. 1.

FIG. 4 shows substrate structures of embodiments of the present invention.

FIG. 5 shows substrate structures of embodiments of the present invention.

FIG. 6 shows a substrate manufacturing method of one embodiment of the present invention.

FIG. 7 shows a substrate manufacturing method of one embodiment of the present invention.

### EMBODIMENTS OF THE PRESENT INVENTION

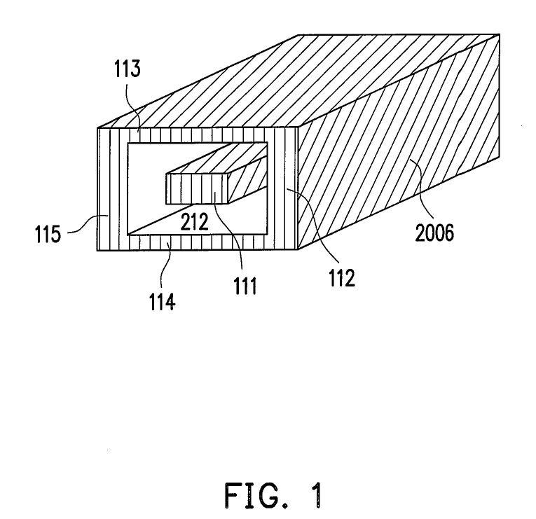

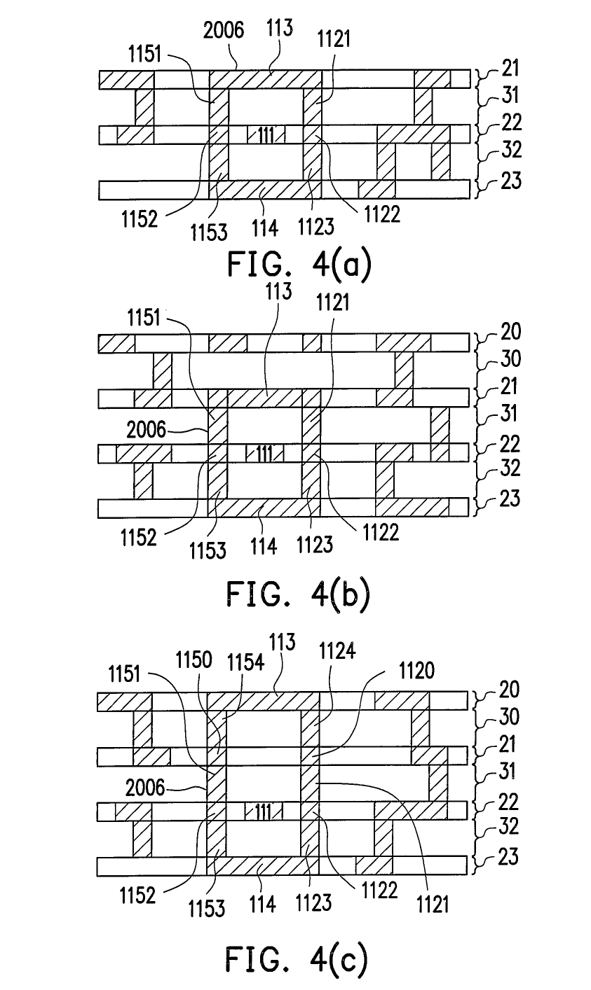

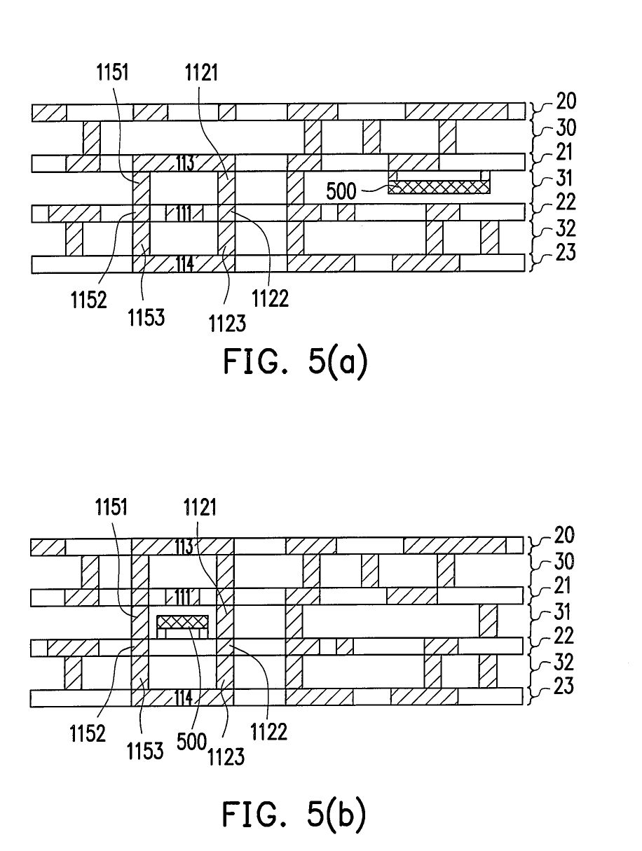

The present invention provides embodiments of a circuit board that has a coaxial signal trace. The circuit board has a plurality of circuit layers, and the structure of the coaxial signal trace is shown in FIGS. 1-3. See FIG. 1. The coaxial signal trace comprises a conductive line 111, a conductive wall 2006 encompassing the conductive line 111, and a dielectric region 212 disposed between the conductive line 111 and the conductive wall 2006. The conductive wall 2006 is composed of conductive lines 112, 113, 114, 115, and these conductive lines are disposed in circuit layers of the circuit board. Additionally, the coaxial signal trace may be applied to circuit boards related to FIG. 4.

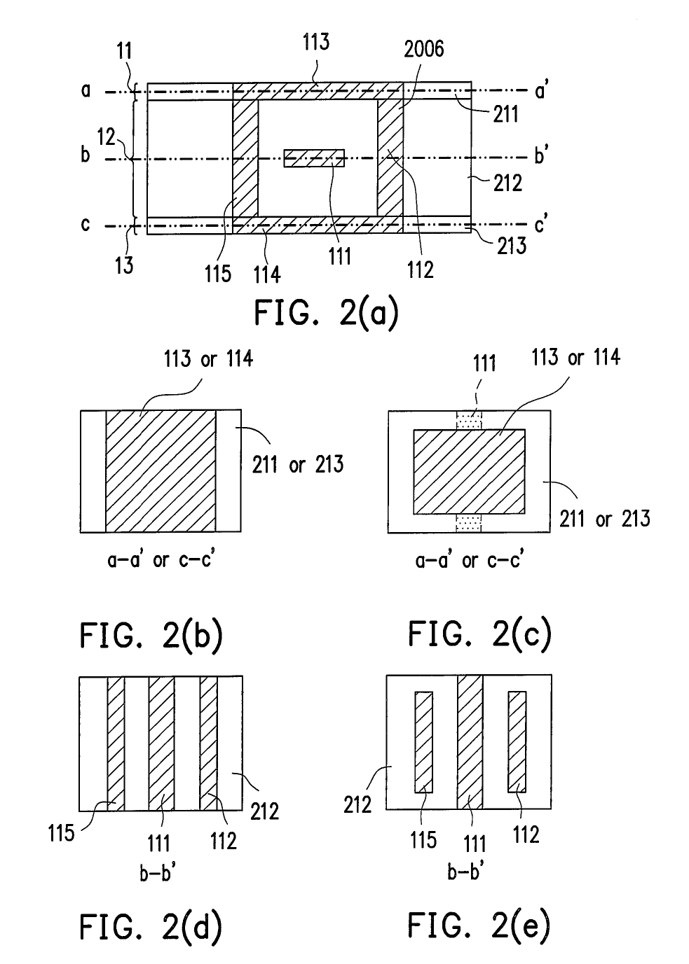

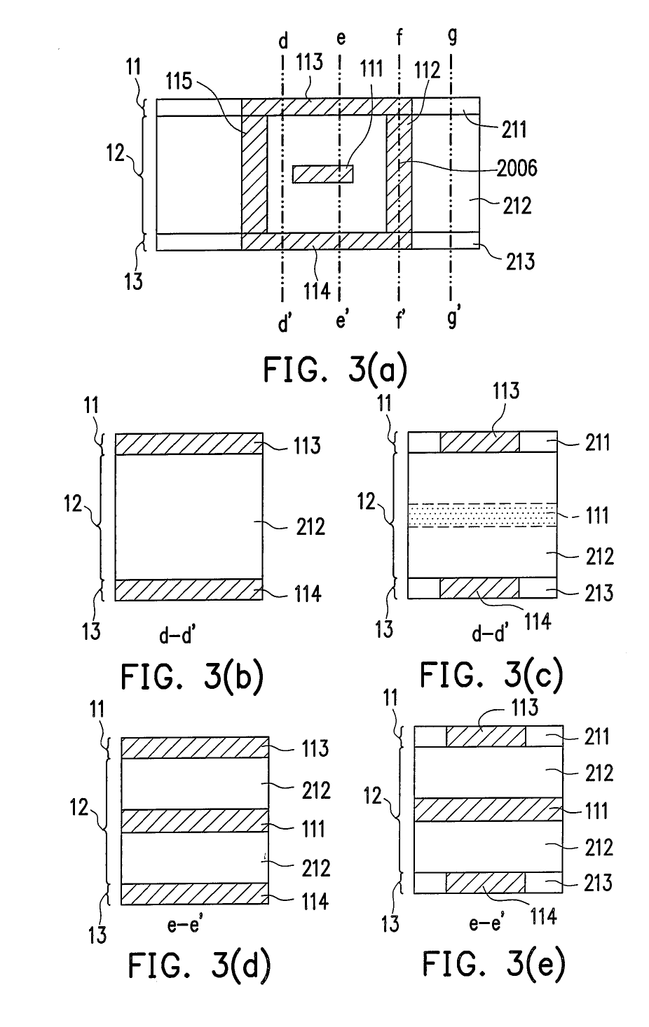

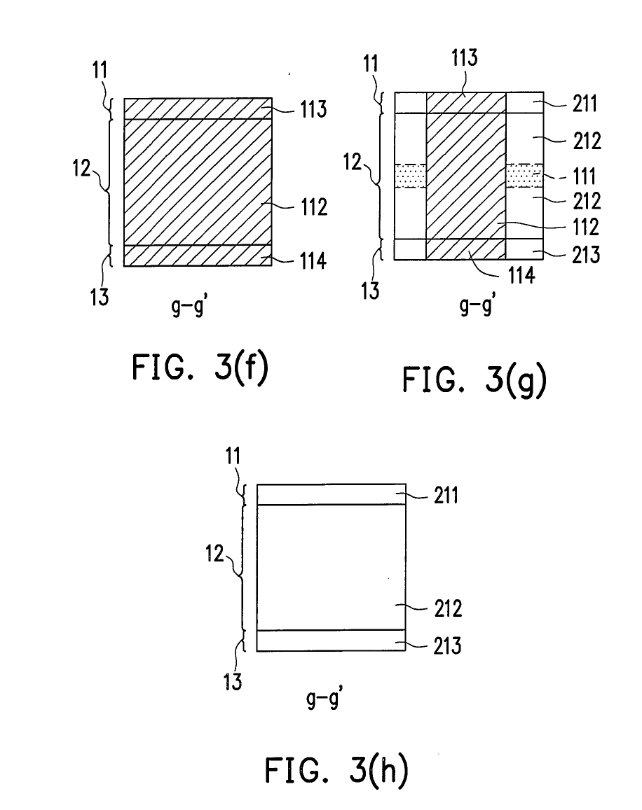

FIGS. 1-3 illustrate the coaxial signal trace structures of the embodiments of the present invention. See FIG. 1 that shows a three-dimensional structure of the coaxial signal trace. See FIG. 2 that shows the top views of different circuit layers of the coaxial signal trace. See FIG. 3 that shows the side views of different vertical cross-sections of the coaxial signal trace.

In the embodiments of the present invention, a coaxial signal trace is formed in the circuit layers 11, 12, 13. The conductive lines 111, 112, 115 are formed in the circuit layer 12, the conductive line 113 is formed in the circuit layer 11, and the conductive line 114 is formed in the circuit layer 13. Besides, a circuit layer may be composed of conductive materials and dielectric materials. That is, the circuit layer 11 may be composed of the conductive line 113 and dielectric region 211, the circuit layer 13 may be composed of the conductive line 114 and dielectric region 213, and the circuit layer 12 may be composed of the conductive lines 111, 112, 115 and dielectric region 212.

See FIG. 2. FIG. 2(a) shows a cross-section view of coaxial signal traces of the embodiments of the present invention, and the cross-section view includes the cross-section lines a-a′, b-b′, c-c′. FIGS. 2(b) and 2(c) respectively show the cross-section views of the cross-section lines a-a′ or c-c′. FIGS. 2(d) and 2(e) show the cross-section views of the cross-section line b-b′. Additionally, the conductive wall 2006, composed of the conductive lines 112, 113, 114, 115, may encompass all of the conductive line 111 in the horizontal direction, as shown in FIG. 2(b) or FIG. 2(d). On the other hand, the conductive wall 2006 may encompass part of the conductive line 111 in the horizontal direction, as shown in FIG. 2(c) or FIG. 2(e).

See FIG. 3. FIG. 3(a) shows a cross-section view of coaxial signal traces of the embodiments of the present invention, and the cross-section view includes the cross-section lines d-d′, e-e′, f-f′, g-g′. However, these cross-section lines respectively stand for the side cross-section views of the coaxial signal trace. FIGS. 3(b) and 3(c) show the cross-section view of the cross-section line d-d′. FIGS. 3(d) and 3(e) show the cross-section view of the cross-section line e-e′. FIGS. 3(f) and 3(g) show the cross-section view of the cross-section line f-f′. FIG. 3(h) shows the cross-section view of the cross-section line g-g′. Additionally, the conductive wall 2006, composed of the conductive lines 112, 113, 114, 115, may encompass all of the conductive line 111 in the horizontal direction, as shown in FIG. 3(b), FIG. 3(d) or FIG. 3(f). On the other hand, the conductive wall 2006 may encompass part of the conductive line l 1l in the horizontal direction, as shown in FIG. 3(c), FIG. 3(e) or FIG. 3(g).

In the embodiments of the present invention, the conductive line 111 may have some connection members (not shown in the drawings) to connect upward or downward to the surfaces of the circuit board. As the connection members run in the direction vertical to the surfaces of the circuit board, there is another conductive wall that continues to encompass all or part of the connection members. Additionally, the connection member may be a via, a Plated Through Hole (PTH), or other connection members used for connecting circuits of different circuit layers.

See FIG. 4. FIGS. 4(a), 4(b), and 4(c) show other embodiments of the present invention, where these circuit boards all have a plurality of circuit layers. Besides, in FIG. 4(a), a coaxial signal trace is formed in the region of the circuit layers 21, 22, 23, 31, and 32. In FIGS. 4(b) and 4(c), a coaxial signal trace is formed in the region of the circuit layers 20, 21, 22, 23, 30, 31, and 32. Consequently, a circuit board of the embodiments of the present invention has circuit layers not limited to what FIG. 4 shows, and a coaxial signal trace of the circuit board may be found in a region of more than seven circuit layers. Furthermore, it is enough to have a conductive line 111 disposed in a circuit layer which is inside a conductive wall of a coaxial signal trace.

In FIG. 4(a), a circuit board of the embodiments of the present invention at least comprises a plurality of circuit layers 21, 22, 23, 31, 32, a plurality of conductive lines 111, 113, 1121, 1122, 1123, 114, 1151, 1152, 1153, and a dielectric region disposed among the conductive lines. A conductive wall 2006 that encompasses the conductive line 111 may be composed of the conductive lines 113, 1121, 1122, 1123, 114, 1151, 1152, 1153. In other words, the circuit board 12 of FIG. 2 or FIG. 3may also be separated into several sub-circuit layers. That is, the circuit layer 12 may also include sub-circuit layers 31, 22, 32, where these sub-circuit layers may also be composed of conductive materials and dielectric materials. Additionally, in FIG. 4(a), the conductive line 112 may include the conductive lines 1121, 1122., 1123, and the conductive line 115 may include the conductive lines 1151, 1152, 1153. The conductive lines 1121, 1151 are formed in the sub-circuit layer 3 1, the conductive lines 1122, 111, 1152 are formed in the sub-circuit layer 22, and the conductive lines 1123, 1153 are formed in the sub-circuit layer 32.

In the embodiments of FIG. 4(b), a circuit board at least comprises a plurality of circuit layers 20, 21, 22, 23, 30, 31, 32, a plurality of conductive lines 111, 113, 1121, 1122, 1123, 114, 1151, 1152, 1153, and a dielectric region disposed among the conductive lines. A conductive wall 2006 that encompasses the conductive line 111 may be composed of the conductive lines 113, 1121, 1122, 1123, 114, 1151, 1152, 1153. Besides, there may be two circuit layers 20, 30 above the conductive wall 2006. However, in other embodiments of the present invention, there may be circuit layers below the conductive wall 2006 (or below the circuit layer 23).

It should be noted that the conductive line 111 in FIG. 4(a) or FIG. 4(b) may also be disposed in the circuit layer 22, circuit layer 32, or circuit layer 31.

In the embodiments of FIG. 4(c), a circuit board at least comprises a plurality of circuit layers 20, 21, 22, 23, 30, 31, 32, a plurality of conductive lines 111, 113, 1120, 1121, 1122, 1123, 1124, 114, 1150, 1151, 1152, 1153, 1154, and a dielectric region disposed among the conductive lines. A conductive wall 2006 that encompasses the conductive line 111 may be composed of the conductive lines 113, 1120, 1121, 1122, 1123, 1124, 114, 1150, 1151, 1152, 1153, 1154. Besides, in the embodiments of the present invention, there may be circuit layers above the conductive wall 2006 (or above the circuit layer 20). There may be circuit layers below the conductive wall 2006 (or below the circuit layer 23). Moreover, the conductive line 111 may be disposed in the circuit layer 22, circuit layer 32, circuit layer 31, circuit layer 21, or circuit layer 30.

It should be noted that in the embodiments relate FIG. 4, the conductive wall 2006 has a structure that may be referred to as the above descriptions related to FIGS. 1, 2, and 3.

The conductive wall 2006 related to the embodiments may function as a ground trace. In other words, the conductive wall 2006 may be a ground trace itself, or it 2006 may connect to other ground traces. Hence, a circuit board of the embodiments of the present invention has a ground structure that comprises a conductive wall.

A circuit board of the embodiments of the present invention may further comprise an electronic device that may connect to circuit layers electrically. The number of electronic devices may be one or more than one. Additionally, an electronic device may be a chip with package or a chip without package. An electronic device may also be a passive device, for example, a capacitor, an inductor, a resistor, and so on.

See FIG. 5. A circuit of the embodiments of the present invention has an electronic device 500. The electronic device 500 may be disposed outside the coaxial signal trace, as shown in FIG. 5(a). On the other hand, the electronic device 500 may be disposed within the coaxial signal trace, as shown in FIG. 5(b).

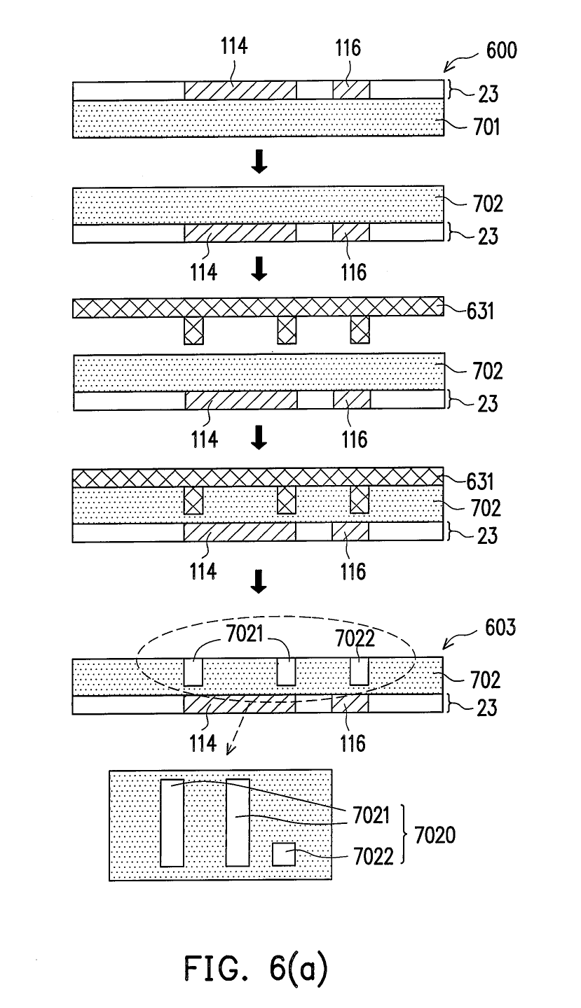

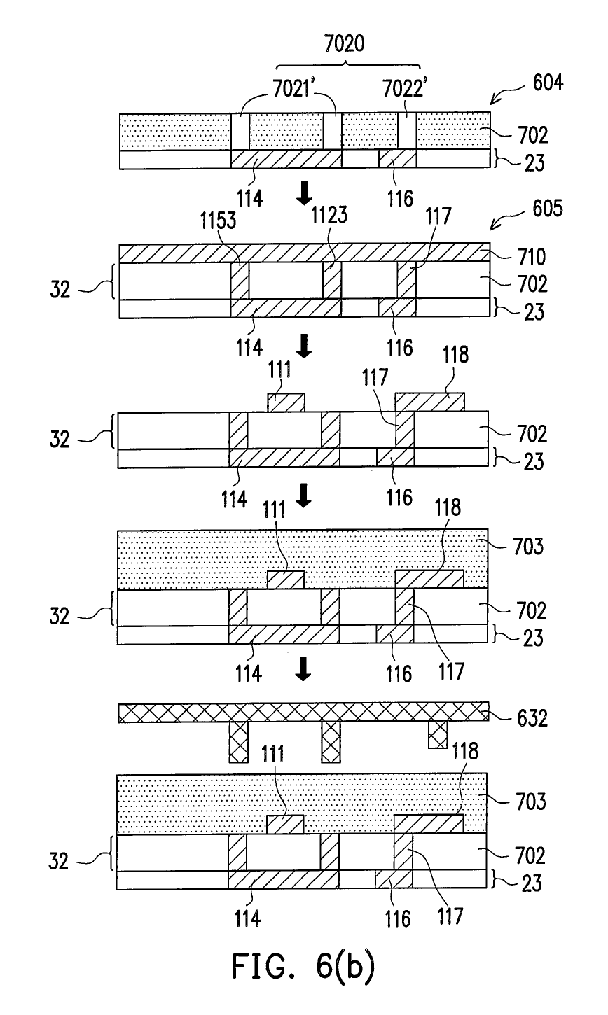

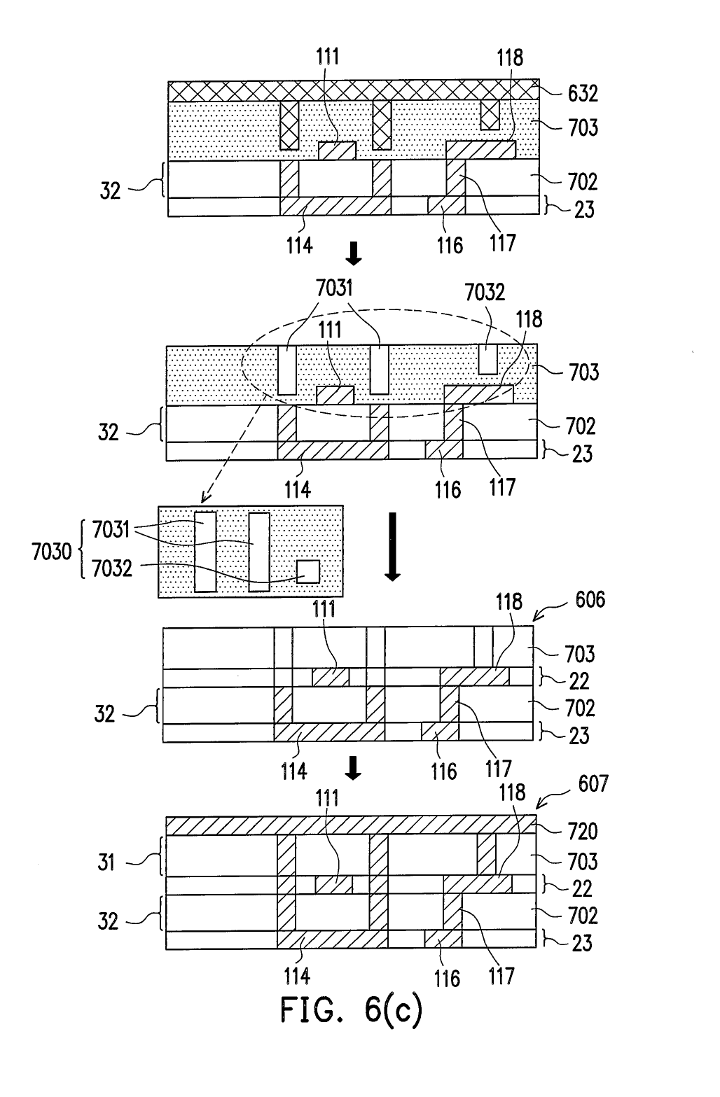

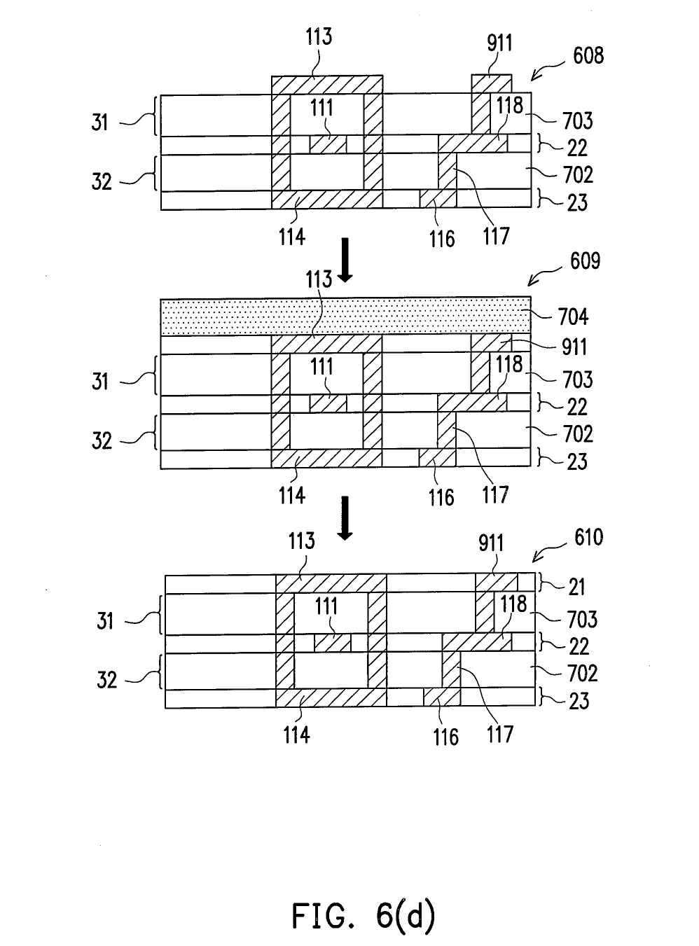

FIGS. 6(a)-6(d) show a substrate manufacturing method of the embodiments of the present invention. Substrates made by this method are a substrate having a coaxial signal trace.

See FIG. 6(a). First, provide a substrate. In the embodiments of the present invention, the substrate may be a substrate 600 comprising a circuit layer 23. The substrate may also be a substrate 701 of no circuit layer 23. If a substrate of no circuit layer 23 is provided, the circuit layer 23 must be formed. The method for forming a circuit layer 23 comprises first forming a circuit pattern by lithography and etching processes and later forming a dielectric layer among conductive layers or conductive regions of the circuit patterns. Additionally, the circuit pattern includes conductive lines 114, 116, and the conductive line 114 is part of a coaxial signal trace of the present invention.

It should be noted that in the embodiments of the present invention, the substrate 701 may be of a single layer, or of a plurality of layers. Besides, the substrate 701 may have a circuit layer, or the substrate 701 may not have circuit layers.

See FIG. 6(a). After the substrate 600 is formed, a dielectric layer 702 is formed on the circuit layer 23. Then, use a mold 631 to compress it into the dielectric layer 702 to have a circuit pattern 7020. The circuit pattern 7020 comprises conductive line features 7021, 7022. Thus, an intermediate subject 603 is formed.

See FIG. 6(b). After the intermediate subject 603 is formed, dielectric materials in the conductive line features of the circuit pattern are removed to have part of the circuit layer 23 exposed. Therefore, an intermediate subject 604 is formed, and the intermediate subject 604 has conductive line features 7021′, 7022′. Then, after the intermediate subject 604 is completed, a conductive layer 710 is formed on the intermediate subject 604, and the circuit pattern 7020 is filled with conductive materials. So an intermediate subject 605 is completed. A circuit layer 32 shown in FIG. 4(a) is formed.

See FIG. 6(b). After the intermediate subject 605 is formed, a circuit pattern is formed by lithography and etching methods, and the circuit pattern includes conductive lines 111, 118. Then, a dielectric layer 703 is formed on the circuit layer 32. Later, a mold 632 is used to compress it into the dielectric layer 703 to have a circuit pattern 7030 that includes conductive line features 7031, 7032. Finally, the dielectric materials in the conductive line features of the circuit pattern are removed to have part of the circuit layers 22, 32 exposed. Consequently, an intermediate subject 606 is formed in FIG. 6(c). After the intermediate subject 606 is formed, a conductive layer 720 is formed on the intermediate subject 606, and conductive materials are used to fill in the circuit pattern 7030. Therefore, an intermediate subject 607 is finished. Now, the circuit layers 22, 31 shown in FIG. 4(a) are completed.

See FIG. 6(d). After the intermediate subject 607 is formed, a circuit pattern, comprising conductive lines 113, 911, is formed by lithography and etching methods. Hence, an intermediate subject 608 is formed. Then, a dielectric layer 704 is formed on the circuit layer 31 to have an intermediate subject 609. If the goal is to produce a circuit board shown in FIG. 4(a), a desired circuit board 610 is finished. However, if more circuit layers are required, based on the intermediate subject 608 or 609, the process methods provided by the embodiments of the present invention or other process method of producing circuit boards may be applied to manufacturing a circuit board of the present invention.

However, there are alternative methods for making the circuit layers 22, 31 shown in FIG. 4(a).

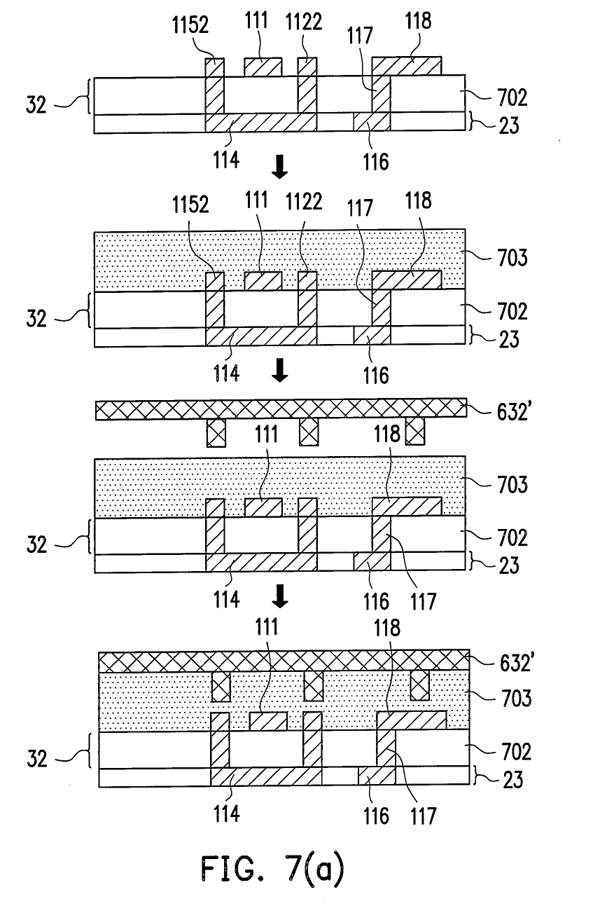

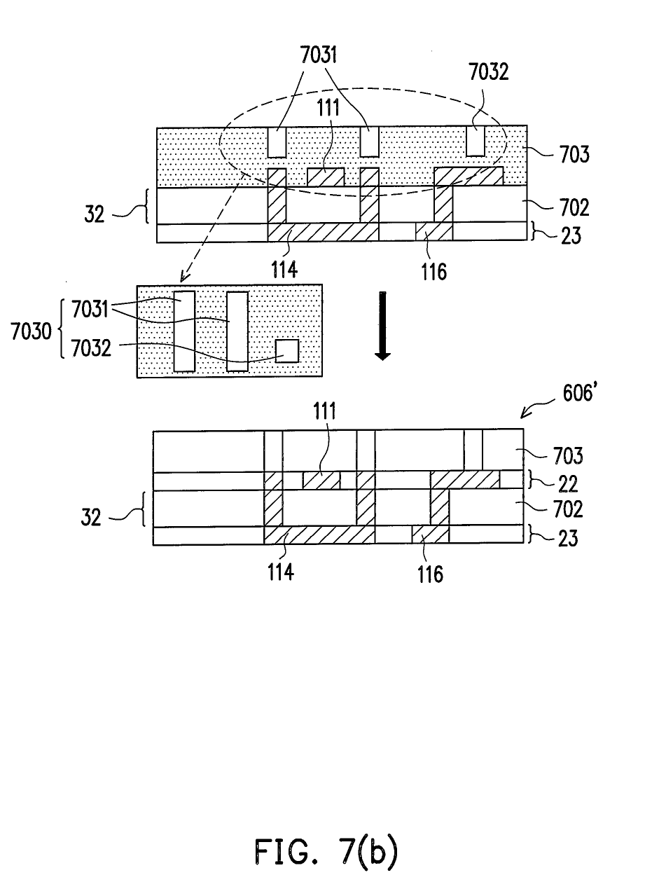

See FIG. 7(a). After the intermediate subject 605 is formed, it is required to form circuit layers 22, 31 shown in FIG. 4(a). First, a circuit pattern is formed by lithography and etching methods, and the circuit pattern comprises conductive lines 111, 1152, 1122, 118. Then, a dielectric layer 703 is formed on the circuit layer 32. Then, a mold 632′ is used to compress into the dielectric layer 703 to have a circuit pattern 7030 that comprises conductive line features 7031, 7032. Finally, the dielectric materials in the conductive line features of the circuit pattern are removed to expose part of the circuit layer 22. As a result, an intermediate subject 606′ is formed in FIG. 7(b). See FIG. 6(c) again. After the intermediate subject 606′, a conductive layer 720 is formed on the intermediate subject 606′, and conductive materials are used to fill in the circuit pattern 7030. Hence, an intermediate subject 607 is formed. Now, the circuit layers 22, 31 shown in FIG. 4(a) are finished.

In the present invention, a method of removing the dielectric materials in the conductive line features may be a desmear method, for example, a wet desmear method (e.g. acidic solutions) and dry desmear method (e.g. plasma-typed desmear method). However, a drilling method, for example, laser drilling or mechanical drilling, may also be applied to removing the dielectric materials in the conductive line features.

In the present invention, a method of forming the dielectric layers 702, 703 on the circuit layer may be a coating method, a lamination method, or a dipping method.

In the present invention, at the steps of forming the conductive line features 7021, 7031, the used mold may only be designed for the conductive line features 7021, 7031. The rest features of the circuit layers 31, 32, may be formed by drilling after the features 7021, 7031 are formed. Additionally, the drilling method may be, for example, laser drilling or mechanical drilling.

In the present invention, a plating method may be applied to forming the conductive layers 710, 720. Besides, the materials of the conductive layers 710, 720 may be metal, for example, Cu, Fe, Al, Sn, Ni, Pb, and so on, or alloy, or conductive polymers, or conductive ceramics. Moreover, the materials of the conductive layers 710, 720 may be other conductive materials.

In the present invention, before the conductive layer 710 or 720 is formed, a step of curing for the dielectric layer 702 or 703 may be carried out. This curing step may be implemented during the step of compressing a mold into the dielectric layer or after the circuit pattern 7020 or 7030 is formed.

In the present invention, the dielectric layers 702, 703 may be polymer materials, for example, unsaturated polyester, polyester, polyimide, polytetrafluoetylene (PTFE), perfluorinated ethylene-propylene copolymer (FEP), and so on. Besides, the dielectric layers 702, 703 may also be composite materials, for example, cyanate ester glass, polyimide glass, Ajinomoto Build-up Film (ABF), and so on.

In the embodiments of the present invention, the dielectric layers 702, 703 may be resin, for example, synthetic resin, thermosetting resin, thermoplastic resin, photosensitive resin, and so on. More specifically, the examples comprise epoxy resin, phenolic resin, polyester resin, polyimide resin, bismaleimide-triazine resin, acrylic resin, melamine formaldehyde resin, polyfunctional epoxy resin, brominated epoxy resin, epoxy novolac, fluroresin, silicone resin, silane, and so on.

Through the circuit boards provided by the present invention, the undesired problems, coming from the signal transmission from a chip to a printed circuit board or package carrier, can be reduced. Because the above-mentioned conductive wall is a ground trace, it can function to isolate the conductive line 111 (a signal trace) from surrounding circuits. Therefore, the problems can be solved, for example, impedance, electromagnetic coupling, cross talk, propagation delay, attenuation, skew, rise time degradation, and so on.

Though the present invention has been disclosed above by a plurality of embodiments, they are not intended to limit the invention. Anybody skilled in the art can make some modifications and variations without departing from the spirit and scope of the invention. Therefore, the protecting range of the present invention falls in the appended claims.

What is claimed is:

1. A circuit board, at least comprising:
a first circuit layer having a signal trace, wherein the first circuit layer has a first side and a second side;
a second circuit layer disposed on the first side of the first circuit layer;
a third circuit layer disposed on the second side of the first circuit layer; and
a first conductive wall disposed in the first circuit layer, the second circuit layer, and the third circuit layer, wherein the first conductive wall encompasses the signal trace.

2. The circuit board of the claim 1, wherein the first conductive wall comprises a first conductive line and a second conductive line, the first conductive line and the second conductive line being disposed in the first circuit layer, the signal trace being disposed between the first conductive line and the second conductive line.

3. The circuit board of the claim 1, further comprising at least one electronic device, wherein the electronic device is disposed in one of the first circuit layer, the second circuit layer, and the third circuit layer.

4. The circuit board of the claim 1, further comprising a ground structure, wherein the ground structure comprises the first conductive wall.

5. The circuit board of the claim 1, wherein the second circuit layer at lease comprises a first connection member connecting to the signal trace.

6. The circuit board of the claim 5, wherein the second circuit layer further comprises a second conductive wall encompassing the first connection member.

7. A substrate manufacturing method, at least comprising:
providing a substrate having a first conducive line;
forming a first dielectric layer on the substrate;
forming a first pattern in the first dielectric layer by a first mold;
forming a first circuit layer in the dielectric layer, wherein the first circuit layer at least comprises a second conductive line and a third conductive line;
forming a second circuit layer in the first dielectric layer, wherein the second circuit layer at least comprises a fourth conductive layer;
forming a second dielectric layer on the first dielectric layer;
forming a second pattern in the second dielectric layer by a second mold;
forming a third circuit layer in the second dielectric layer, wherein the third circuit layer at least comprises a fifth conductive line and a sixth conductive line; and
forming a fourth circuit layer on the second dielectric layer, wherein the fourth circuit layer at least comprises a seventh conductive line,
wherein a conductive wall is made of the first conductive line, the second conductive line, the third conductive line, the fifth conductive line, the sixth conductive line, and the seventh conductive line, and the conductive wall encompasses the fourth conductive line.

8. The substrate manufacturing method of claim 7, further comprising: curing the dielectric layer after the dielectric layer is formed.

9. The substrate manufacturing method of claim 7, further comprising: curing the dielectric layer during the step of forming the pattern.

10. The substrate manufacturing method of claim 7, wherein the steps of forming the circuit layer comprises a plating method.

11. The substrate manufacturing method of claim 7, wherein the steps of forming the circuit layer comprises lithography and etching methods.

12. The substrate manufacturing method of claim 7, wherein the steps of forming the circuit layer comprises a desmear method.

13. The substrate manufacturing method of claim 7, wherein the steps of forming the circuit layer comprises a drilling method.

14. A circuit board, at least comprising:
a plurality of circuit layers;
a signal trace disposed in one of the circuit layers; and
a first conductive wall encompassing the trace signal and disposed in the circuit layers.

15. The circuit board of claim 14, wherein the circuit layers at lease comprise:
a first circuit layer, wherein the signal trace is disposed in the first circuit layer;
a second circuit layer disposed on one side of the first circuit layer; and
a third circuit layer disposed on the other side of the first circuit layer,
wherein the first conductive wall is disposed in the first circuit layer, the second circuit layer, and the third circuit layer.

16. The circuit board of claim 14, wherein the first conductive wall at least comprises:
a first conductive line; and
a second conductive line,
wherein the first conductive line, the second conductive line, and the signal trace are disposed in the same circuit layer, the signal trace being disposed between the first conductive line and the second conductive line.

17. The circuit board of claim 16, wherein the first conductive wall at least comprises:
a third conductive line;
a fourth conductive line; and
a fifth conductive line,
wherein the third conductive line, the fourth conductive line, and the fifth conductive line are disposed in the second circuit layer, the third conductive line connecting to the first conductive line, the fourth conductive line connecting to the second conductive line, and the third conductive line being connected to the fourth conductive line via the fifth conductive line.

18. The circuit board of claim 14, further comprising a ground structure.

19. The circuit board of claim 14, further comprising at least a first connection member connecting to the signal trace.

20. The circuit board of claim 14, further comprising one electronic device disposed in one of the circuit layers.
